(19) United States
(12) Patent Application Publication
(10) Pub. No.: US 2024/0090114 A1
(43) Pub. Date: Mar. 14, 2024

(54) INVERTER MODULE

(71) Applicant: LS ELECTRIC CO., LTD., Anyang-si, Gyeonggi-do (KR)

(72) Inventor: Jae Moon LEE, Anyang-si, Gyeonggi-do (KR)

(21) Appl. No.: 18/273,173

(22) PCT Filed: Jan. 4, 2022
(86) PCT No.: PCT/KR2022/000056

§ 371 Date: Jul. 19, 2023

(30) Foreign Application Priority Data
Jan. 26, 2021 (KR) 10-2021-0010914

(51) Int. Cl. H05K 1/02; H05K 1/18; H05K 7/20

(52) U.S. Cl. CPC H05K 1/0201; H05K 1/18; H05K 7/20909; H05K 7/20927; H05K 2201/10901; H05K 2201/2045

(57) ABSTRACT

The present disclosure relates to an inverter module comprising: a power module coupled to a PCB; a thermal pad positioned between the PCB and the power module to prevent foreign substances from being attached to the PCB and the power module and to conduct heat; and a cooling device including a heat sink attached to the power module to cool the power module.

### CROSS-REFERENCE TO RELATED APPLICATION

This application is the National Stage filing under 35 U.S.C. 371 of International Application No. PCT/KR2022/000056, filed on Jan. 4, 2022 which claims priority to and the benefit of Korean Patent Application No. 10-2021-0010914, filed on Jan. 26, 2021, the disclosure of which is incorporated herein by reference in its entirety.

### FIELD

The present disclosure relates to an inverter module, and more specifically to an inverter module for controlling the driving of an electric motor.

### BACKGROUND

In general, the inverter is a type of power conversion device that converts a DC voltage into an AC voltage.

Conventionally, three-phase AC power is converted into DC through a rectifier, and DC power stored in a DC link (usually a capacitor) is converted into AC power by using an inverter to drive a motor.

The inverter is a VVVF (Variable Voltage Variable Frequency) system, and it controls the speed of a motor by varying the voltage and frequency that are input to the motor according to the pulse width modulation (PWM) output.

The inverter is a circuit composed of power semiconductors and is implemented on a typical PCB.

The power semiconductors that make up the inverter are diodes, thyristors, IGBTs (Insulated Gate Bipolar Transistors), MOSFETs and the like, and since high power is used, heat is generated, and thus, a cooling device for heat dissipation must be essentially provided.

Korean Registered Patent No. 10-1777439 of the Applicant of the present disclosure (registered on Sep. 5, 2017, COOLING DEVICE FOR INVERTER) describes a device for dissipating heat in an inverter in the air-cooling manner.

For heat dissipation of the inverter, an air-cooling type may be used as shown in Korean Registered Patent No. 10-1777439, and various methods such as a water-cooling type may be used.

An inverter module may be understood as a combination of an inverter and a heat dissipation device.

As another example of the related art, Korean Registered Patent No. 10-1800048 (registered on Nov. 15, 2017, COOLING DEVICE FOR INVERTER) of the Applicant of the present disclosure also describes the structure of an inverter in which a cooling device is combined.

Korean Registered Patent No. 10-1800048 describes a structure in which a PCB and a cooling device are combined such that power devices are mounted on a PCB, and the power devices are located in a housing in which a cooling fan is provided.

That is, the method is used in which heat sinks contacting the power devices are located in a cooling device, and heat exchange occurs in the heat sinks by using a cooling fan.

Although not clearly described in the related art described above, when a power device or a power module, which is an assembly of power devices, is mounted on a PCB, various processes are performed in consideration of the coupling state of the cooling device.

FIG. 8 is a schematic configuration diagram of a conventional inverter module, and FIG. 9 is a diagram of the coupling configuration of the power module and the PCB in FIG. 8.

Referring to FIGS. 8 and 9, in the conventional inverter module, a power module 300 is mounted on a PCB 100, and a heat sink 220 is attached to the power module 300.

The power module 300 and the heat sink 220 are bonded by using a heat conductive adhesive such as thermal grease.

The heat sink 220 is located in the housing of the cooling device 200, and has a configuration in which heat is radiated by forced convection by the cooling fan 210.

In this case, in the power module 300, a plurality of pins 310 protrude, and the pins 310 are coupled to the coupling holes of the PCB 100.

The pins 310 are electrically connected to the PCB 100 by soldering.

That is, the power module 300 enables electrical connection by using a solder 110 to each of the pins 310 protruding from the opposite surface of one surface of the PCB 100 to which the power module 300 is coupled.

In this case, the soldering method performs automatic soldering by using a manual or automatic machine.

In addition, the solder 110 may be formed by using a known soldering method such as wave soldering and the like, in which the PCB 100 to which the power module 300 is coupled is moved while being in contact with a solder melt.

However, since all of these soldering methods use heat, there is a risk of damage or deformation of components such as a PCB and the like due to heat, and there is a problem in that productivity is low because a relatively long required work time is necessary.

Although not illustrated in the drawings, the physical coupling between the power module 300 and the PCB 100 is performed by a physical coupling means such as a bolt and the like.

Although the PCB 100 is a conventional PCB, the coating layer 120 may be formed on a part of the PCB 100 to prevent damage that may occur due to the inflow and attachment of foreign substances due to forced convection or the like.

Since external foreign substances may adhere to the PCB 100 and cause a short circuit accident due to the conductive foreign substances, the coating layer 120 is applied to at least the conductive part of the PCB 100 in order to prevent the same.

However, the coating layer 120 cannot be applied between the PCB 100 and the power module 300 due to the bonding structure.

That is, the pins 310 are exposed between the PCB 100 and the power module 300, and there is no coating layer 120 on the surface of the PCB 100, and the conductive layers such as wiring and the like are exposed.

In such a state, when a conductive foreign substance is attached to the PCB 100 or the exposed pins 310, the insulation distance is reduced, and there has been a problem in that insulation breakdown or a short circuit accident may occur.

In addition, since the air layer is positioned between the PCB 100 and the power module 300, the heat dissipation performance using the cooling device 200 is deteriorated.

That is, there has been a problem in that the heat dissipation effect is reduced because the transfer of heat between the PCB 100 and the power module 300 is not made by conduction but by convection of air.

### SUMMARY

The problem to be solved by the present disclosure in view of the above problems is directed to providing an inverter module which is capable of increasing dust-proof and heat-dissipation efficiency.

In addition, another problem to be solved by the present disclosure is directed to providing an inverter module which is capable of reducing the time required for an assembly process.

In order to solve the above technical problems, the inverter module of the present disclosure may include a power module which is coupled to a PCB; a thermal pad which is positioned between the PCB and the power module to prevent foreign substances from being attached to the PCB and the power module and to conduct heat; and a cooling device which comprises a heat sink attached to the power module to cool the power module.

In an exemplary embodiment of the present disclosure, the PCB may include a conductive bushing terminal that provides a through-hole, and pins of the power module may be fitted and coupled to the bushing terminal.

In an exemplary embodiment of the present disclosure, each of the pins may include a double-branched elastic structure in which a void is formed in the center of a part that is inserted into the bushing terminal.

In an exemplary embodiment of the present disclosure, the thermal pad may include insertion holes that are penetrated and inserted such that the pins are not interfered with.

In an exemplary embodiment of the present disclosure, the thermal pad may have a lower hardness than those of the PCB and the power module, and have elasticity.

In an exemplary embodiment of the present disclosure, in each of the insertion holes, one pin or a plurality of pins may be inserted according to the distance between the pins.

In an exemplary embodiment of the present disclosure, the power module may include a support which protrudes from a surface on which the pins protrude to support the PCB.

In an exemplary embodiment of the present disclosure, the PCB may be coupled to the support by a coupling member.

In an exemplary embodiment of the present disclosure, the cooling device may be an air-cooling type or a water-cooling type.

In an exemplary embodiment of the present disclosure, the distance between the PCB and the power module may be adjusted by a flat plate on which the power module coupled to the thermal pad is seated, and an external support which protrudes from the upper part of the flat plate to fix an edge of the PCB such that the height can be adjusted.

Since the present disclosure prevents conductive foreign substances from being attached to the pins of a power module or a PCB by applying a thermal pad between the power module and the PCB, it has the effect of preventing the occurrence of a short circuit accident or insulation breakdown due to conductive foreign substances.

In addition, the present disclosure has the effect of increasing the heat dissipation effect by the application of a thermal pad.

Moreover, the present disclosure can prevent deformation or damage to the thermal pad due to heat during the soldering process by not using soldering when the PCB, the thermal pad and the power module are combined, and has the effect of improving the productivity by shortening the bonding process time.

### BRIEF DESCRIPTION OF THE DRAWINGS

FIG. 1 is a block diagram of an inverter module according to a preferred exemplary embodiment of the present disclosure.

FIG. 2 is an enlarged view of the main part of FIG. 1.

FIG. 3 is an exploded perspective view of FIG. 2.

FIG. 4 is a front view of the power module.

FIG. 5 is a plan view of the state in which the power module and the thermal pad are combined.

FIG. 6 is a state diagram of the coupling state between the power module and the PCB on which the thermal pad is seated.

FIG. 7 is an exemplary diagram of the device for adjusting a gap between the PCB and the power module.

FIG. 8 is a block diagram of a conventional inverter module.

FIG. 9 is a diagram illustrating the coupling relationship between the PCB and the power module in FIG. 8.

### EXPLANATION OF REFERENCE NUMERALS

| | |
|---|---|
| 10: PCB | 11: Bushing terminal |
| 11a: Separation prevention unit | 20: Cooling device |
| 21: Cooling fan | 22: Heat sink |
| 30: Power module | 31: Pin |
| 32: Void | 33: Elastic structure |
| 35: Housing | 36: Support |
| 40: Thermal pad | 41: Insertion hole |

### DETAILED DESCRIPTION

In order to fully understand the configurations and effects of the present disclosure, preferred exemplary embodiments of the present disclosure will be described with reference to the accompanying drawings. However, the present disclosure is not limited to the exemplary embodiments disclosed below, and it may be embodied in various forms, and various modifications may be made. However, the description of the present exemplary embodiments is provided to complete the disclosure of the present disclosure, and to fully inform the scope of the disclosure to those of ordinary skill in the art to which the present disclosure pertains. In the accompanying drawings, components are enlarged in size than actual for the convenience of description, and the ratios of each component may be exaggerated or reduced.

Terms such as ‘first’ and ‘second’ may be used to describe various elements, but the elements should not be limited by the above terms. The above terms may be used only for the purpose of distinguishing one element from another. For example, without departing from the scope of the present disclosure, a ‘first component’ may be termed a ‘second component’, and similarly, a ‘second component’ may also be termed a ‘first component’. In addition, the singular expression includes the plural expression unless the context clearly dictates otherwise. Unless otherwise defined, terms used in the exemplary embodiments of the present disclosure may be interpreted as meanings commonly known to those of ordinary skill in the art.

Hereinafter, the inverter module according to an exemplary embodiment of the present disclosure will be described in detail with reference to the drawings.

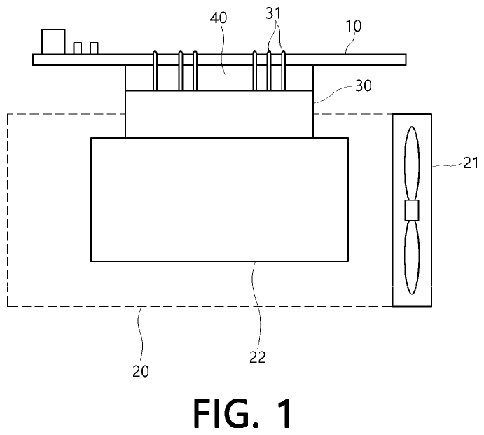

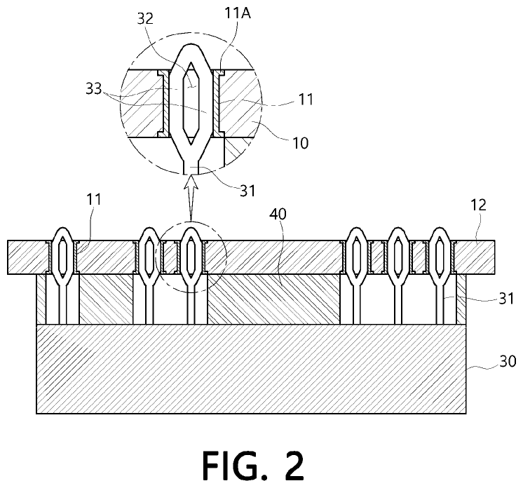

FIG. 1 is a block diagram of an inverter module according to a preferred exemplary embodiment of the present disclosure, and FIG. 2 is an enlarged view of the main part of FIG. 1.

Referring to FIGS. 1 and 2, respectively, the inverter module of the present disclosure is configured by including a power module 30 which is mounted on a PCB 10, a thermal pad 40 which is positioned between the power module 30 and the PCB 10 to prevent foreign substances from being introduced and to conduct heat, a heat sink 22 which is attached to the power module 30, and a cooling device unit 20 in which the heat sink 22 is accommodated and which cools the heat sink 22 by forced convection by a cooling fan 21

Hereinafter, the configuration and operation of the inverter module of the present disclosure configured as described above will be described in more detail.

First of all, the cooling device unit 20 may dissipate heat from the heat sink 22 by forming forced convection using the cooling fan 21.

Such a configuration of the cooling device unit 20 is an example, and a water cooling-type cooling device unit which is formed with a cooling water pipe in contact with the heat sink 22 may be used, and in addition, a structure using a known cooling method of the heat sink 22 may be applied.

The power module 30 attached to the heat sink 22 may be a power element constituting an inverter circuit or an assembly of power elements.

For example, the power device may be a diode, a thyristor, an insulated gate bipolar transistor (IGBT) or a MOSFET.

The power module 30 is adhered to the heat sink 22 by a thermally conductive adhesive.

The power module 30 is configured by including a metal housing and a plurality of pins 31 protruding outward from the metal housing.

The pins 31 of the power module 30 are electrically connected by being fitted and inserted to the PCB 10, and this coupling method will be described in more detail below.

The present disclosure does not use a soldering process by fitting the pins 31, and thus, the time required for the assembling process can be shortened. The reduction of the process time contributes to the improvement of productivity.

In addition, by not using a soldering process accompanied by heat, it is possible to prevent deformation or damage to the PCB 10, and particularly, it is possible to prevent deformation or damage to the thermal pad 40, which will be described below.

For the fitting between the power module 30 and the PCB 10, a bushing terminal 11, which is a conductor, is inserted into the through-hole in the PCB 10. The bushing terminal 11 may be electrically connected to the conductor wiring of the PCB 10.

The bushing terminal 11 is to provide an electrical contact surface with the pins 31, and the shape or material may be variously changed and used.

However, when the pin 31 is press-fitted into the bushing terminal 11, it is preferable to have a strong structure such that the bushing terminal 11 does not separate from the PCB 10.

For example, a separation preventing part 11A protruding outwardly may be formed on the upper and lower portions of the bushing terminal 11.

The pins 31 include a bifurcated elastic structure 33 in which a void 32 is formed in the center of a portion inserted into the bushing terminal 11. The portion where the elastic structure 33 is located forms a larger diameter portion with respect to the other regions of the pin 31.

Therefore, when press-fitting into the bushing terminal 11, the gap between the elastic structures 33 is reduced in a direction in which the width of the void 32 decreases, and it is firmly fixed in a state of being in close contact with the bushing terminal 11 by the restoring force of the elastic structure 33.

The pins 31 pass through the thermal pad 40, and thus, in a state where the pins 31 are coupled to the bushing terminal 11 of the PCB 10, the thermal pad is positioned between the PCB 10 and the power module 30.

Preferably, both surfaces of the thermal pad 40 are in close contact with the PCB 10 and the power module 30, respectively.

It is preferable that a coating layer 12 is formed on the entire surface of the PCB 10 except for the contact portion of the thermal pad 40 that is structurally difficult to form a coating layer.

The coating layer 12 prevents the conductor portion from being exposed to the outside, and serves as a means to prevent short circuit and the like, even when a conductive foreign substance is attached.

In addition, since the thermal pad 40 is fixed in close contact with a portion of the PCB 10 on which the coating layer 12 is not formed, it is possible to prevent foreign substances from adhering, and thus, it has a feature of preventing damage, malfunction and failure that may occur due to the attachment of conductive foreign substances.

Moreover, the thermal pad 40 prevents exposure of the side portion of the pins 31 and closely adheres to the protruding surface of the pin 31 of the power module 30 such that since it is possible to prevent conductive foreign substances from being attached to the pin 31s or the power module 30, damage such as insulation breakdown may be prevented.

The thermal pad 40 can use thermally conductive silicone, thermally conductive resin and thermally conductive rubber material, and by using relatively low hardness and elastic material compared to the PCB 10 and the power module 30, it has a feature of preventing damage to the power module 30 and the PCB 10 due to external vibrations, and also to prevent damage due to impact in the assembly process.

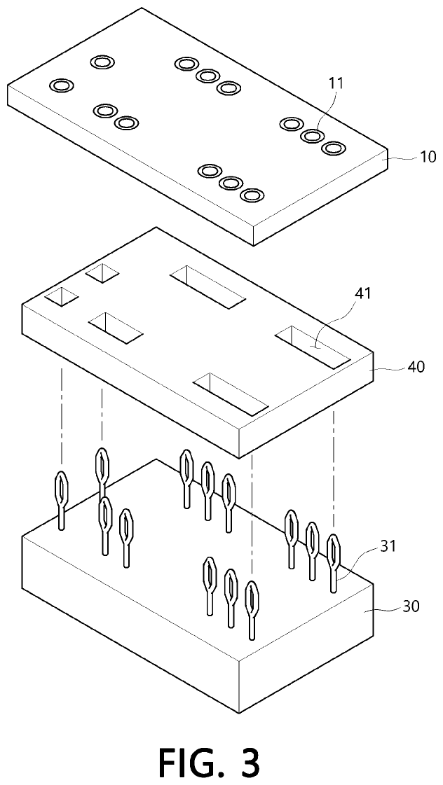

FIG. 3 is an exploded perspective view of FIG. 2.

Referring to FIG. 3, the thermal pad 40 includes an insertion hole 41 into which at least one or more pins 31 are inserted.

It is advantageous for manufacturing and assembly processes that the planar shape of the insertion hole 41 has a rectangular structure, but the present disclosure is not necessarily limited to the rectangular structure.

The condition of the insertion hole 41 is that the diameter is larger than the diameter of the elastic structure 33, which is the large diameter portion of the pin 31, and thus, the pins 31 can be inserted without interference.

Therefore, the region of the insertion hole 41 may be determined such that all the pins 31 concentrated in a region having a relatively narrow installation interval may penetrate through one insertion hole 41.

If interference occurs when the pins 31 are inserted into the insertion hole 41, difficulties in the manufacturing process may occur in that bending of the pin 31 occurs, or more attention should be paid when coupling the thermal pad 40 to the power module 30.

The pin 31 which is located at a position that is significantly spaced apart from the other pins 31 may be inserted into one insertion hole 41 alone.

While the pins 31 are inserted into the insertion hole 41 of the thermal pad 40, the elastic structure 33 is exposed to the upper side of the thermal pad 40, so as to be coupled to the conductive bushing terminal 11 of the PCB 10 in the subsequent process.

The coupling with the bushing terminal 11 can be easily understood from the description with reference to FIG. 2.

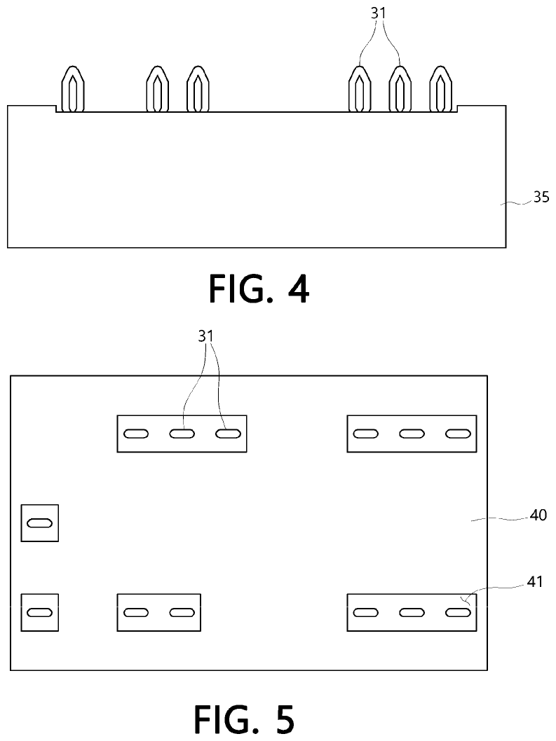

FIG. 4 is a front configuration diagram of the power module 30 applied to the present disclosure.

Referring to FIG. 4, the power module 30 includes a housing 35 and a plurality of pins 31 that are insulated from the housing 35 and protrude to the outside. It may be understood that the housing 35 is for protecting power elements inside the power module 30, and the pins 31 are for supplying and outputting power.

The power module 30 applied to the present disclosure includes a support 36 protruding along the periphery of the housing 35 to support the PCB 10.

The support 36 may have an independently protruding structure, and may be a continuous protruding portion along the periphery of one surface of the housing 35.

The support 36 protrudes from the periphery of the protruding surface of the pin 31, and the end of the protruding portion is a flat surface such that the PCB 10 can be seated.

Preferably, the protruding height of the support 36 is the same as the height of the thermal pad 40 or lower than the height of the thermal pad 40.

For more robust coupling, fastening holes may be formed in the support 36 vertically, and the PCB 10 may be fastened by a coupling member such as a bolt and the like.

Accordingly, the distance between the power module 30 and the PCB 10 may be determined by the height of the support 36.

FIG. 5 is a plan view of a state in which the thermal pad 40 is seated on the power module 30 of FIG. 4.

Referring to FIG. 5, as described above, a plurality of insertion holes 41 are formed in the thermal pad 40, and a plurality of pins 31 or a single pin 31 may be inserted into one insertion hole 41.

The size and shape of the insertion hole 41 are designed according to the installation position and spacing of the pins 31.

In particular, the insertion hole 41 is designed to be larger than the diameter of the pin 31 so as not to interfere with the insertion of the pins 31.

While the thermal pad 40 having the insertion hole 41 is seated in the power module 30, the PCB 10 is coupled to the pins 31 in a state where the elastic structures 33 of the pins 31 are exposed to the upper portion of the thermal pad 40.

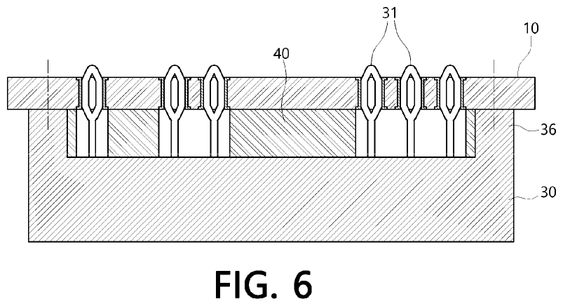

The coupled state is illustrated in FIG. 6.

That is, the PCB 10 is equipped with bushing terminals 11 at the insertion position of the pin 31 in advance, and the PCB 10 is aligned such that the elastic structures 33 are simultaneously coupled to each of the bushing terminals 11, and it may be fastened by applying a downward pressure.

Therefore, a separate soldering process is not required, and assembly time can be shortened.

In addition, by not using a thermal process for assembling, there is a feature of preventing damage or deformation of parts due to heat.

In the present disclosure, since the thermal pad 40 is positioned between the PCB 10 and the power module 30, the conduction of heat is possible through the thermal pad 40, and thus, the heat dissipation effect can be increased.

In addition, since the thermal pad 40 itself acts as a vibration-proof structure for the pins 31, the region where the coating layer 12 of the PCB 10 is not formed and one surface of the power module 30, it has a feature of preventing damage due to the attachment of conductive foreign substances.

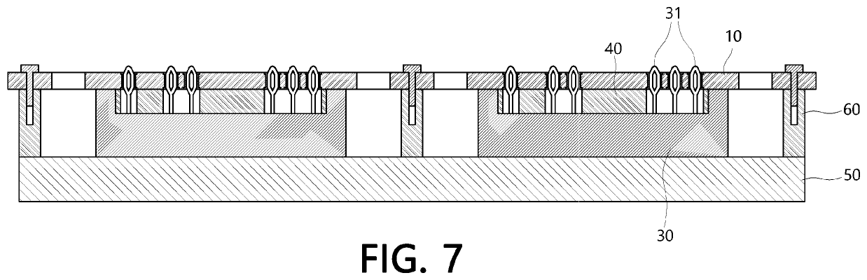

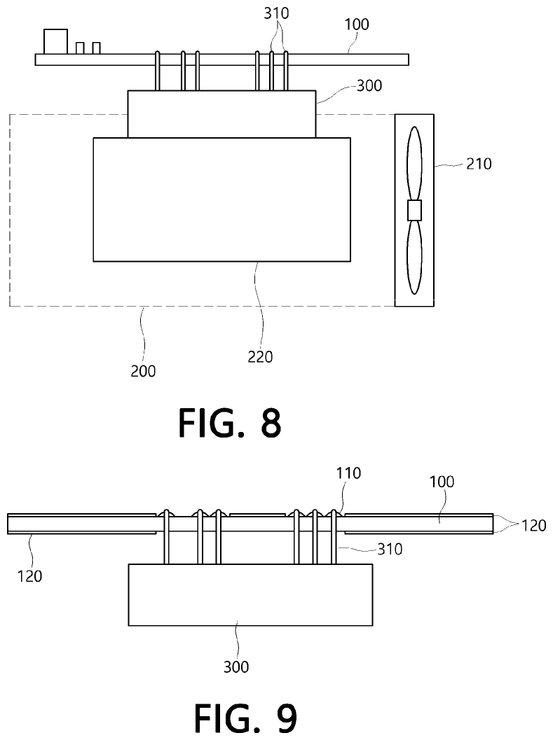

FIG. 7 is a configuration diagram of an exemplary embodiment of a jig for coupling of the present disclosure.

Referring to FIG. 7, a combination of the power module 30 and the thermal pad 40 may be placed on a flat plate 50, and the PCB 10 may be coupled to the pins 31 of the power module 30.

In this case, an external support 60 is fixed to the upper portion of the flat plate 50, and the edge of the PCB 10 may be fixed to the external support 60 to fix the height.

That is, by using the external support 60, it is possible to couple while maintaining a gap between the power module 30 and the PCB 10.

Although the exemplary embodiments according to the present disclosure have been described above, these are merely exemplary, and those of ordinary skill in the art will understand that various modifications and equivalent ranges of exemplary embodiments are possible therefrom. Accordingly, the true technical protection scope of the present disclosure should be defined by the following claims.

The present disclosure relates to a technique for protecting the power module and the PCB of an inverter by using the laws of nature, and thus has industrial applicability.

1. An inverter module, comprising:
a power module which is coupled to a PCB;
a thermal pad which is positioned between the PCB and the power module to prevent foreign substances from being attached to the PCB and the power module and to conduct heat; and
a cooling device which comprises a heat sink attached to the power module to cool the power module.

2. The inverter module of claim 1, wherein the PCB comprises a conductive bushing terminal that provides a through-hole, and
wherein pins of the power module are fitted and coupled to the bushing terminal.

3. The inverter module of claim 2, wherein each of the pins comprises a double-branched elastic structure in which a void is formed in the center of a part that is inserted into the bushing terminal.

4. The inverter module of claim 2, wherein the thermal pad comprises insertion holes that are penetrated and inserted such that the pins are not interfered with.

5. The inverter module of claim 4, wherein the thermal pad has a lower hardness than those of the PCB and the power module, and has elasticity.

6. The inverter module of claim 4, wherein in each of the insertion holes, one pin or a plurality of pins are inserted according to the distance between the pins.

7. The inverter module of claim 4, wherein the power module comprises a support which protrudes from a surface on which the pins protrude to support the PCB.

8. The inverter module of claim 7, wherein the PCB is coupled to the support by a coupling member.

9. The inverter module of claim 4, wherein the cooling device is an air-cooling type or a water-cooling type.

10. The inverter module of claim 4, wherein the distance between the PCB and the power module is adjusted by a flat plate on which the power module coupled to the thermal pad is seated, and an external support which protrudes from the upper part of the flat plate to fix an edge of the PCB such that the height can be adjusted.
